(19) United States
(12) Patent Application Publication
(10) Pub. No.: US 2023/0387149 A1
(43) Pub. Date: Nov. 30, 2023

(54) OPTICAL SENSOR

(71) Applicant: HAMAMATSU PHOTONICS K.K., Hamamatsu-shi, Shizuoka (JP)

(72) Inventors: Mitsuhito MASE, Hamamatsu-shi, Shizuoka (JP); Ryo TAKIGUCHI, Hamamatsu-shi, Shizuoka (JP); Hiroaki ISHII, Hamamatsu-shi, Shizuoka (JP); Masaru NAKANO, Hamamatsu-shi, Shizuoka (JP); Shin-ichiro TAKAGI, Hamamatsu-shi, Shizuoka (JP)

(73) Assignee: HAMAMATSU PHOTONICS K.K., Hamamatsu-shi, Shizuoka (JP)

(21) Appl. No.: 18/027,730

(22) PCT Filed: Oct. 8, 2021
(86) PCT No.: PCT/JP2021/037386

§ 371 Date: Mar. 22, 2023

(30) Foreign Application Priority Data
Oct. 14, 2020 (JP) 2020-173134

(51) Int. Cl. H01L 27/146; H01L 31/107; H01L 31/0224

(52) U.S. Cl. CPC H01L 27/14609; H01L 27/14643; H01L 31/107; H01L 31/022408

(57) ABSTRACT

Provided is an optical sensor including: a charge generation region that generates charges in response to incident light; a charge collection region to which charges generated in the charge generation region are transferred; and at least one transfer gate electrode disposed on a transfer region between the charge generation region and the charge collection region. The charge generation region includes an avalanche multiplication region that causes avalanche multiplication, and a gradient potential energy formation region that forms gradient potential energy that is gradient so that potential energy becomes lower as approaching the transfer region in the charge generation region.

### TECHNICAL FIELD

An aspect of the present disclosure relates to an optical sensor.

### BACKGROUND ART

As the optical sensor, there is known an optical sensor including a charge generation region configured to generate charge in response to incident light, a charge collection region to which the charges generated in the charge generation region are transferred, and a transfer gate electrode disposed on a region between the charge generation region and the charge collection region (for example, refer to Patent Literature 1). In the optical sensor, the charges can be transferred from the charge generation region to the charge collection region at a high speed.

### CITATION LIST

### Patent Literature

Japanese Unexamined Patent Publication No. 2015-5752

### SUMMARY OF INVENTION

### Technical Problem

In the optical sensor as described above, it may be required to enlarge an area of the charge generation region so as to broaden a light-receiving region. However, in a case where the area of the charge generation region is large, since time is taken for movement of charges in the charge generation region, there is a concern that charge transfer from the charge generation region to the charge collection region may be late.

An objective of an aspect of the present disclosure is to provide an optical sensor capable of transferring charges at a high speed even in a case where an area of a light-receiving region is large.

### Solution to Problem

According to an aspect of the present disclosure, there is provided an optical sensor including: a charge generation region that generates charges in response to incident light; a charge collection region to which charges generated in the charge generation region are transferred; and at least one transfer gate electrode disposed on a transfer region between the charge generation region and the charge collection region. The charge generation region includes an avalanche multiplication region that causes avalanche multiplication, and a gradient potential energy formation region that forms gradient potential energy in the charge generation region, the gradient potential energy being gradient so that potential energy becomes lower as approaching the transfer region.

In the optical sensor, the charge generation region includes the avalanche multiplication region that causes avalanche multiplication. Accordingly, the avalanche multiplication can be caused in the charge generation region, and high sensitivity can be realized. In addition, the charge generation region includes the gradient potential energy formation region that forms gradient potential energy that is gradient so that potential energy becomes lower as approaching the transfer region in the charge generation region. Accordingly, the gradient potential energy that is gradient so that the potential energy becomes lower as approaching the transfer region can be formed in the charge generation region, and a moving speed of charge in the charge generation region can be increased. Hence, according to the optical sensor, charges can be transferred at a high speed even in a case where an area of a light-receiving region is large.

The at least one transfer gate electrode may include a first transfer gate electrode and a second transfer gate electrode disposed on a side of the charge generation region with respect to the first transfer gate electrode. In this case, as to be described below, suppression of occurrence of a noise, or enlargement of a dynamic range is possible.

In a charge transfer process of transferring the charges generated in the charge generation region to the charge collection region, electric potentials may be applied to the first transfer gate electrode and the second transfer gate electrode so that after first potential energy that is potential energy of a region immediately below the first transfer gate electrode, and second potential energy that is potential energy of a region immediately below the second transfer gate electrode become equal to or lower than potential energy of a boundary portion with the transfer region in the charge generation region, the first potential energy and the second potential energy become higher than the potential energy of the boundary portion. In this case, charges can be transferred from the charge generation region to the charge collection region at a high speed by using the first transfer gate electrode and the second transfer gate electrode, and charges can be suppressed from moving from the charge generation region to the charge collection region after charge transfer.

In the charge transfer process, electric potentials may be applied to the first transfer gate electrode and the second transfer gate electrode so that the second potential energy becomes higher than the first potential energy. In this case, charges can be suppressed from returning from a region immediately below the first transfer gate electrode to the charge generation region, and generation of a noise can be suppressed. In addition, the read-out amount of charges can be increased by using capacity of the region immediately below the first transfer gate electrode, and a dynamic range can be broadened.

In a state in which an electric potential of the first transfer gate electrode and an electric potential of the second transfer gate electrode are equal to each other, the second potential energy may be higher than the first potential energy. In this case, the second potential energy can be made higher than the first potential energy by providing the same electric potential to the first transfer gate electrode and the second transfer gate electrode. As a result, for example, a configuration for providing the electric potential can be simplified in comparison to a case of making the second potential energy higher than the first potential energy by providing electric potentials different in a magnitude to the first transfer gate electrode and the second transfer gate electrode.

The transfer region may include a potential energy adjustment layer for making the second potential energy higher than the first potential energy. In this case, the second potential energy can be made higher than the first potential energy by the potential energy adjustment layer.

In a state in which the first potential energy and the second potential energy in the charge transfer process are equal to or lower than the potential energy of the boundary portion, the second potential energy may be equal to the potential energy of the boundary portion and the first potential energy may be lower than the potential energy of the boundary portion. In this case, charges can be suppressed from being accumulated in a region immediately below the second transfer gate electrode, and occurrence of a noise due to returning of charges to the charge generation region from the region immediately below the second transfer gate electrode can be suppressed.

In the charge transfer process, after the second potential energy becomes higher than the potential energy of the boundary portion from a state in which the first potential energy and the second potential energy are equal to or lower than the potential energy of the boundary portion, the first potential energy may become higher than the potential energy of the boundary portion. In this case, charges can be reliably suppressed from returning to the charge generation region from a region immediately below the first transfer gate electrode, and occurrence of a noise can be reliably suppressed.

The avalanche multiplication region may be formed in a layer shape along a predetermined plane, and when a side where the transfer gate electrode is located with respect to the avalanche multiplication region in a direction orthogonal to the plane is set as a first side, and a side opposite to the first side is set as a second side, the gradient potential energy formation region may be located on the first side with respect to the avalanche multiplication region. In this case, a ratio of charges existing in a region close to the transfer gate electrodes increases, and charges can be transferred at a higher speed. In addition, since the gradient potential energy is formed near the transfer gate electrodes, charges can also be transferred at a higher speed.

The gradient potential energy formation region may include a plurality of semiconductor regions arranged so that an impurity concentration becomes higher as approaching the transfer region. In this case, the gradient potential energy can be preferably formed in the charge generation region.

The gradient potential energy formation region may include a first semiconductor region including a first portion and a second portion, and a second semiconductor region which has an impurity concentration higher than an impurity concentration of the first semiconductor region and is disposed between the first portion and the second portion, and of which a width increases as approaching the transfer region. In this case, the gradient potential energy can be preferably formed in the charge generation region.

The avalanche multiplication region may be formed in a layer shape along a predetermined plane, and when a side where the transfer gate electrode is located with respect to the avalanche multiplication region in a direction orthogonal to the plane is set as a first side, and a side opposite to the first side is set as a second side, the gradient potential energy formation region may be located on the second side with respect to the avalanche multiplication region. In this case, since limitation relating to a gradient height of the gradient potential energy is less likely to occur, the gradient of the gradient potential energy can be enlarged, and charges can be transferred at a higher speed. In addition, since charges collected by the gradient potential energy are multiplicated in the avalanche multiplication region, a multiplication occurrence site can be limited, and uniformity of multiplication can be raised.

The gradient potential energy formation region may include a first semiconductor layer, and a second semiconductor layer located on the second side with respect to the first semiconductor layer, and the gradient potential energy may be formed due to formation of a stepped portion between the first semiconductor layer and the second semiconductor layer. In this case, the gradient potential energy can be preferably formed in the charge generation region.

A through-hole may be formed in the first semiconductor layer, and the through-hole may overlap a boundary portion with the transfer region in the charge generation region in a direction orthogonal to the plane. In this case, charges guided by the gradient potential energy can be collected in the boundary portion with the transfer region in the charge generation region.

The charge generation region may have an embedded photodiode structure. In this case, occurrence of a dark current in the charge generation region can be suppressed.

### Advantageous Effects of Invention

According to the aspect of the present disclosure, it is possible to provide an optical sensor capable of transferring charges at a high speed even in a case where an area of a light-receiving region is large.

### BRIEF DESCRIPTION OF DRAWINGS

FIG. 1 is a configuration diagram of an optical detection device according to an embodiment.

FIG. 2 is a cross-sectional view taken along line II-II in FIG. 1.

FIGS. 3(a) and 3(b) are potential energy distribution diagrams describing an operation example of an optical sensor.

FIGS. 4(a) and 4(b) are potential energy distribution diagrams describing an operation example of the optical sensor.

FIG. 5 is a potential energy distribution diagram describing an operation example of an optical sensor according to a first modification example.

FIG. 6 is a plan view of an optical sensor according to a second modification example.

FIG. 7 is a cross-sectional view of an optical sensor according to a third modification example.

### DESCRIPTION OF EMBODIMENTS

Hereinafter, an embodiment of the present disclosure will be described in detail with reference to the accompanying drawings. In the following description, the same reference numeral will be given to the same or equivalent element, and redundant description will be omitted.

### [Optical Detection Device]

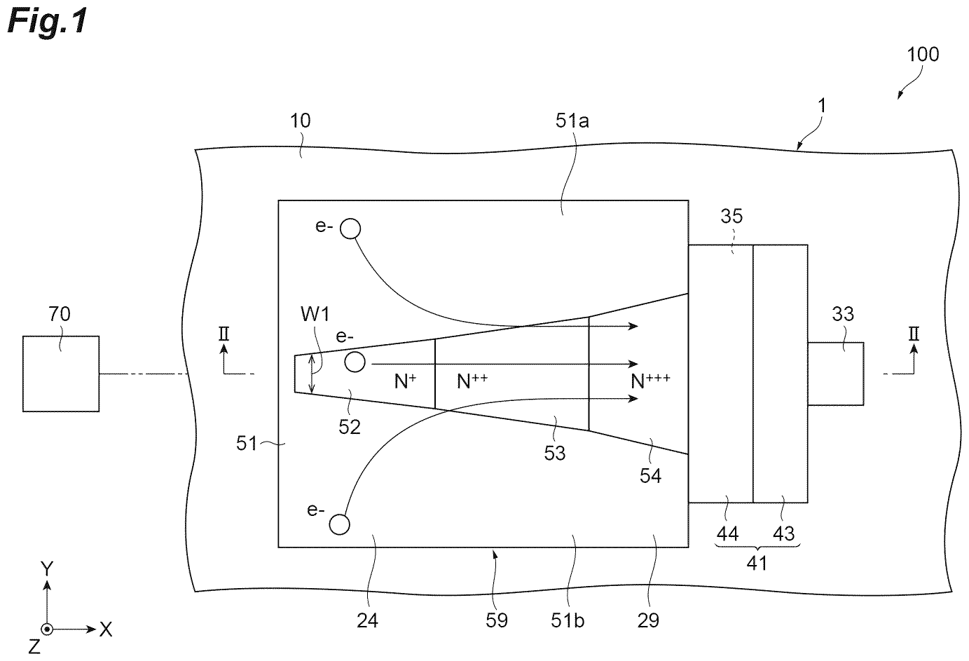

As illustrated in FIG. 1, an optical detection device 100 includes an optical sensor (image sensor) 1, and a control unit 70. The control unit 70 controls the optical sensor 1. For example, the control unit 70 is configured as an on-chip integrated circuit mounted on a semiconductor substrate that constitutes the optical sensor 1, but may be configured separately from the optical sensor 1.

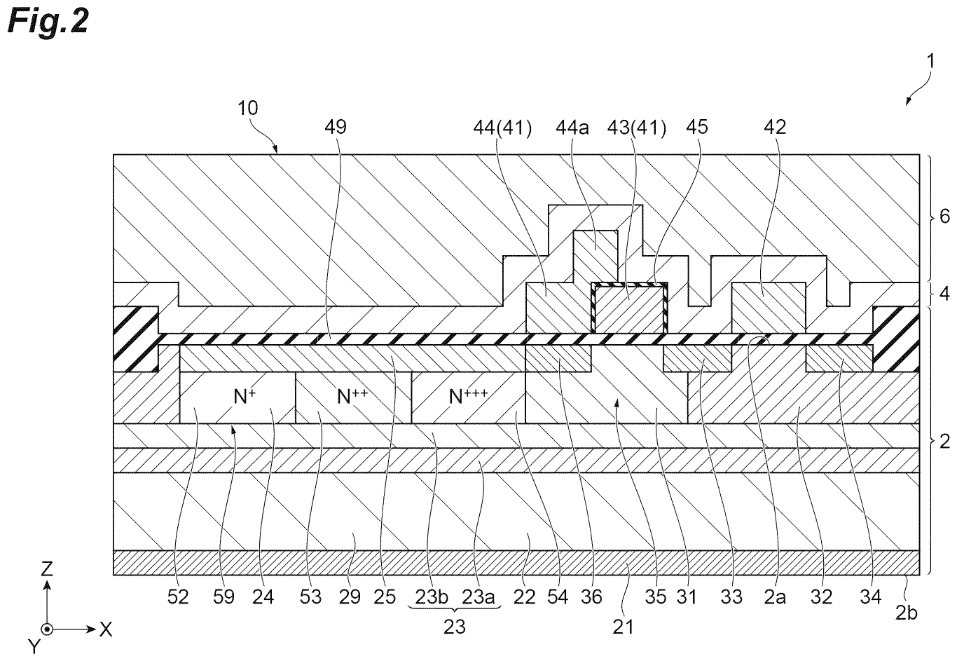

As illustrated in FIG. 1 and FIG. 2, the optical sensor 1 includes a semiconductor layer 2, an electrode layer 4, and a protective layer 6. The semiconductor layer 2 includes a first surface 2a and a second surface 2b. The second surface 2b is a surface on a side opposite to the first surface 2a. The optical sensor 1 includes a plurality of pixels 10 arranged along the first surface 2a. For example, the plurality of pixels 10 are two-dimensionally arranged along the first surface 2a. Hereinafter, a thickness direction of the semiconductor layer 2 is set as a Z-direction, one direction orthogonal to the Z-direction is set as an X-direction, and a direction orthogonal to both the Z-direction and the X-direction is set as a Y-direction. In addition, one side in the Z-direction is set as a first side, and the other side in the Z-direction is set as a second side (side opposite to the first side). In FIG. 1, illustration of partial configurations (a part of the electrode layer 4, the protective layer 6, and the like) is omitted.

Each pixel 10 includes a semiconductor region 21, a semiconductor region 22, an avalanche multiplication region 23, a charge accumulation region 24, an interposition region 25, well regions 31 and 32, a charge collection region 33, and a channel region 34 in the semiconductor layer 2. The respective regions 21 to 26, and 31 to 34 are formed by performing various kinds of processing (for example, etching, film formation, impurity injection, and the like) on a semiconductor substrate (for example, a silicon substrate).

The semiconductor region 21 is a p-type (first conductivity type) region, and is formed in a layer shape along the second surface 2b in the semiconductor layer 2. A carrier concentration of the semiconductor region 21 is higher than a carrier concentration of the semiconductor region 22. It is preferable that the thickness of the semiconductor region 21 is as thin as possible. As an example, the semiconductor region 21 is a p-type region having a carrier concentration (impurity concentration) of 1×10¹⁶ cm⁻³ or more, and the thickness thereof is approximately 1 μm. Note that, the semiconductor region 21 may be formed by accumulation by a transparent electrode formed on the second surface 2b via an insulating film.

The semiconductor region 22 is a p-type region, is formed in a layer shape in the semiconductor layer 2, and is located on the first side with respect to the semiconductor region 21. As an example, the semiconductor region 22 is a p-type region having a carrier concentration of 1×10¹⁵ cm⁻³ or less, and the thickness thereof is 2 μm or more and is approximately 10 μm as an example.

The avalanche multiplication region 23 includes a first multiplication region 23a and a second multiplication region 23b. The first multiplication region 23a is a p-type region, is formed in a layer shape in the semiconductor layer 2, and is located on the first side with respect to the semiconductor region 22. As an example, the first multiplication region 23a is a p-type region having a carrier concentration of 1×10¹⁶ cm⁻³ or more, and the thickness thereof is approximately 1 μm. The second multiplication region 23b is an n-type (second conductivity type) region, is formed in a layer shape in the semiconductor layer 2, and is located on the first side with respect to the first multiplication region 23a. As an example, the second multiplication region 23b is an n-type region having a carrier concentration of 1×10¹⁶ cm⁻³ or more, and the thickness thereof is approximately 1 μm. The first multiplication region 23a and the second multiplication region 23b form a pn junction. The avalanche multiplication region 23 is a region that causes avalanche multiplication.

The charge accumulation region 24 is an n-type region, is formed in a layer shape in the semiconductor layer 2, and is located on the first side with respect to the avalanche multiplication region 23. As an example, the thickness of the charge accumulation region 24 is approximately 1 μm. Details of the charge accumulation region 24 will be described later.

The interposition region 25 is a p-type region, is formed in a layer shape along the first surface 2a in the semiconductor layer 2, and is located on the first side with respect to the charge accumulation region 24. That is, the interposition region 25 has a conductivity type different from that of the charge accumulation region 24. The semiconductor region 21, the semiconductor region 22, the first multiplication region 23a, the second multiplication region 23b, the charge accumulation region 24, and the interposition region 25 are formed in a layer shape along an XY plane (plane orthogonal to the Z-direction), and are arranged in this order along the Z-direction. As an example, the interposition region 25 is a p-type region having a carrier concentration of 1×10¹⁵ cm⁻³ or more, and the thickness thereof is approximately 0.2 μm.

The charge accumulation region 24 and the interposition region 25 form a pn junction, and constitute an embedded photodiode. That is, a charge generation region 29 has an embedded photodiode structure. The semiconductor regions 21 and 22, the avalanche multiplication region 23, the charge accumulation region 24, and the interposition region 25 function as the charge generation region (light absorption region, a photoelectric conversion region) 29 that generates charges in response to incident light. In other words, the charge generation region 29 includes the semiconductor regions 21 and 22, the avalanche multiplication region 23, the charge accumulation region 24, and the interposition region 25.

The well regions 31 and 32 are p-type regions, and are formed in a layer shape along the first surface 2a in the semiconductor layer 2. The well regions 31 and 32 are located on the first side with respect to the avalanche multiplication region 23. The well region 31 is disposed to be adjacent with the charge accumulation region 24 and the interposition region 25 in the X-direction. The well region 32 is disposed to surround the charge accumulation region 24, the interposition region 25, and the well region 31 when viewed from the Z-direction. As an example, the well regions 31 and 32 are p-type regions having a carrier concentration of 1×10¹⁶ to 5×10¹⁷ cm⁻³, and the thickness thereof is approximately 1 μm. The well regions 31 and 32 constitute a plurality of read-out circuits (for example, source follower amplifiers, reset transistors, and the like). The plurality of read-out circuits are electrically connected to the charge collection region 33.

The charge collection region 33 and the channel region 34 are formed in the well regions 31 and 32. The charge collection region 33 is an n-type region, is formed in a layer shape along the first surface 2a in the semiconductor layer 2, and is disposed at a boundary portion between the well regions 31 and 32. As an example, the charge collection region 33 is an n-type region having a carrier concentration of 1×10¹⁸ cm⁻³ or more, and the thickness thereof is approximately 0.2 μm. The charge collection region 33 functions as floating diffusion. The channel region 34 is an n-type region, is formed in a layer shape along the first surface 2a in the semiconductor layer 2, and is disposed in the well region 32. The interposition region 25, the charge collection region 33, and the channel region 34 are arranged along the X-direction in this order. In the example in FIG. 1, a width (a length along the Y-direction) of the charge collection region 33 is smaller than a width (a length along the Y-direction) of a fourth region 54, but the width of the charge collection region 33 may be approximately the same as the width of the fourth region 54. In this case, charge transfer is smoothly performed due to a transfer path with the same width.

The electrode layer 4 is provided on the first surface 2a of the semiconductor layer 2. Each pixel 10 includes a transfer gate electrode 41 and a discharge gate electrode 42 in the electrode layer 4. The transfer gate electrode 41 and the discharge gate electrode 42 are formed in the electrode layer 4, and are disposed on the first surface 2a of the semiconductor layer 2 via an insulating layer 49. For example, the insulating layer 49 is a silicon nitride film, a silicon oxide film, or the like. For example, the transfer gate electrode 41 and the discharge gate electrode 42 are formed from polysilicon.

The transfer gate electrode 41 is disposed on a transfer region 35 between the interposition region 25 and the charge collection region 33 in the well region 31. The transfer region 35 is a region immediately below the transfer gate electrode 41. The transfer gate electrode 41 includes a first transfer gate electrode 43 and a second transfer gate electrode 44. The second transfer gate electrode 44 is disposed on a side of the interposition region 25 with respect to the first transfer gate electrode 43. Note that, in this specification, “a region immediately below any electrode” means a region that overlaps the electrode in the Z-direction.

The second transfer gate electrode 44 is formed to ride over the first transfer gate electrode 43, and includes a ride-over portion 44a disposed on the first transfer gate electrode 43. An insulating layer 45 is formed on a surface of the first transfer gate electrode 43, and the first transfer gate electrode 43 is electrically isolated from the second transfer gate electrode 44 by the insulating layer 45. Each of the first transfer gate electrode 43 and the second transfer gate electrode 44 has a rectangular shape in which a long side is parallel to the Y-direction when viewed from the Z-direction.

A potential energy adjustment layer 36 is formed in the transfer region 35. The potential energy adjustment layer 36 is disposed to overlap the second transfer gate electrode 44 in the Z-direction, and is adjacent to the interposition region 25 in the X-direction. As an example, the potential energy adjustment layer 36 is a P-type region having a carrier concentration of approximately 1×10¹⁵ to 1×10¹⁸ cm⁻³ and the thickness thereof is approximately 0.1 μm.

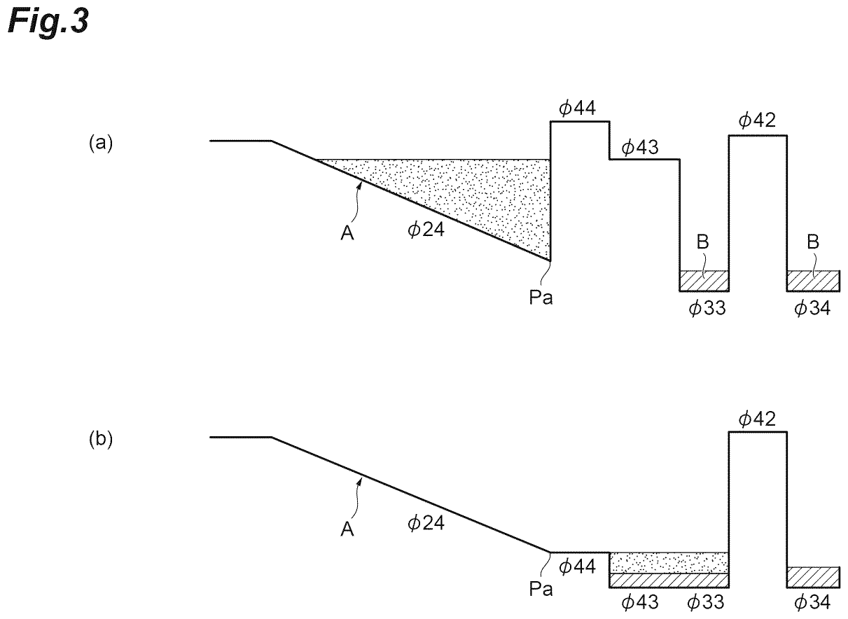

Since the potential energy adjustment layer 36 is formed, as illustrated in FIG. 3(a), second potential energy ϕ44 that is potential energy of a region immediately below the second transfer gate electrode 44 becomes higher than first potential energy ϕ43 that is potential energy of a region immediately below the first transfer gate electrode 43. In FIG. 3(a), a potential energy distribution diagram along the X-direction is shown. In a state illustrated in FIG. 3(a), an electric potential of the first transfer gate electrode 43 and an electric potential of the second transfer gate electrode 44 are equal to each other.

The discharge gate electrode 42 is disposed on a region between the charge collection region 33 and the channel region 34 in the well region 32. For example, the discharge gate electrode 42 has a rectangular shape having two sides facing each other in the X-direction and two sides facing each other in the Y-direction. The electrode layer 4 is covered with the protective layer 6. For example, the protective layer 6 is an insulating layer such as boro-phosphosilicate glass (BPSG) film.

As illustrated in FIG. 1 and FIG. 2, the charge accumulation region 24 includes a first region 51, a second region 52, a third region 53, and a fourth region 54. Each of the regions 51 to 54 is an n-type region. An impurity concentration of the regions 51 to 54 is higher in the order of the first region 51, the second region 52, the third region 53, and the fourth region 54. That is, the second region 52 has an impurity concentration higher than that of the first region 51, the third region 53 has an impurity concentration higher than that of the second region 52, and the fourth region 54 has an impurity concentration higher than that of the third region 53. The impurity concentration of the first region 51 is approximately 1×10¹³ to 1×10¹⁶ cm⁻³. The impurity concentration of the second region 52, the third region 53, and the fourth region 54 is approximately 1×10¹⁶ to 1×10¹⁹ cm⁻³. Note that, the first region 51 may be a p-type region. Even in this case, the potential energy becomes high at a part of the first region 51 due to a depletion layer that is generated between the second region 52, the third region 53, and the fourth region 54, and charges can be accumulated.

The first region 51 has a rectangular shape when viewed from the Z-direction. The second region 52, the third region 53, and the fourth region 54 are arranged in this order along the X-direction. The fourth region 54 is adjacent to the transfer region 35 in the X-direction. That is, the second region 52, the third region 53, and the fourth region 54 are arranged so that an impurity concentration becomes higher as approaching the transfer region 35. When viewed from the Z-direction, the second region 52, the third region 53, the fourth region 54, the second transfer gate electrode 44, the first transfer gate electrode 43, and the charge collection region 33 are arranged in this order along the X-direction. The second region 52, the third region 53, and the fourth region 54 are disposed between a first portion 51a and a second portion 51b of the first region 51 in the Y-direction.

When viewed from the Z-direction, a width (a length along the Y-direction) W1 of a region defined by the second region 52, the third region 53, and the fourth region 54 continuously increases as approaching the transfer region 35. Each of the second region 52, the third region 53, and the fourth region 54 has a trapezoidal shape when viewed from the Z-direction. The width W1 linearly increases in each of the second region 52, the third region 53, and the fourth region 54. The width W1 is continuous in each of a boundary between the second region 52 and the third region 53, and a boundary between the third region 53 and the fourth region 54.

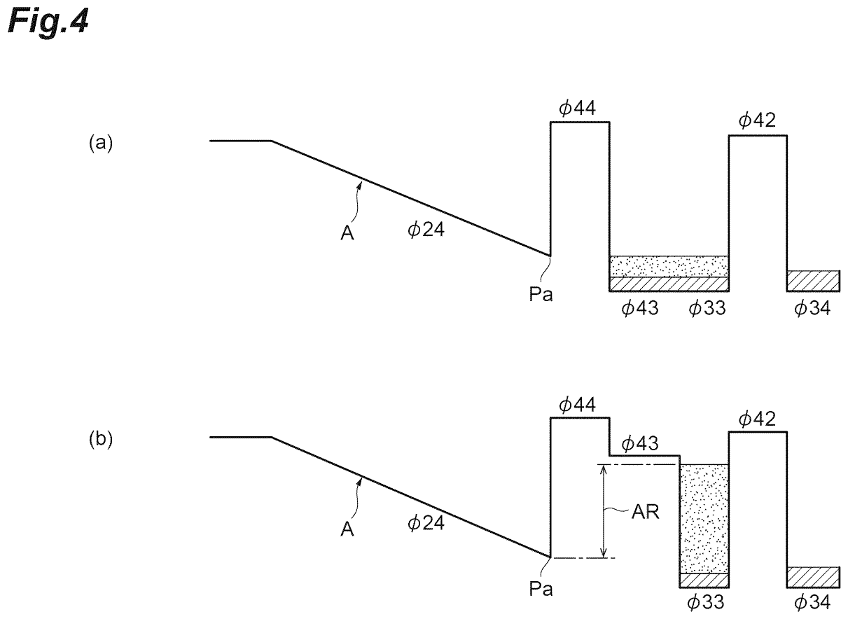

By the charge accumulation region 24 including the first region 51, the second region 52, the third region 53, and the fourth region 54, as illustrated in FIG. 3 and FIG. 4, gradient potential energy A that is gradient so that potential energy becomes lower as approaching the transfer region 35 is formed in the charge accumulation region 24. In FIG. 3 and FIG. 4, a potential energy distribution diagram along the X-direction are shown. In the example, potential energy ϕ24 of the charge accumulation region 24 linearly decreases as approaching the transfer region 35. In this manner, the first region 51, the second region 52, the third region 53, and the fourth region 54 (the charge accumulation region 24) function as a gradient potential energy formation region 59 that forms the gradient potential energy A. The gradient potential energy formation region 59 is located on the first side with respect to the avalanche multiplication region 23 in the Z-direction. The first side is a side where the transfer gate electrode 41 is located with respect to the avalanche multiplication region 23 in the Z-direction.

### [Light Detection Method]

An example of a light detection operation by the optical sensor 1 will be described with reference to FIG. 3 and FIG. 4. The following operation is realized by the control unit 70 controlling the optical sensor 1. More specifically, by the control unit 70 controlling a voltage that is applied to the transfer gate electrode 41 and the discharge gate electrode 42, the operation of the optical sensor 1 is realized. Hereinafter, the operation will be described with focus given to one pixel 10, but this is also true of an operation of another pixel 10.

First, a charge accumulation process of accumulating charges in the charge accumulation region 24 is executed. In the charge accumulation process, a negative voltage (for example, −50 V) is applied to the semiconductor region 21 setting an electric potential of the interposition region 25 as a reference. That is, a reverse bias is applied to a pn junction formed in the avalanche multiplication region 23. Accordingly, an electric field intensity of 3×10⁵ to 4×10⁵ V/cm is generated in the avalanche multiplication region 23. In this state, when light is incident to the semiconductor layer 2 from the second surface 2b, electrons (charges) are generated due to absorption of light in the semiconductor regions 21 and 22. The generated charges are multiplied by the avalanche multiplication region 23 and move to the charge accumulation region 24. In the optical sensor 1, a region that overlaps the charge accumulation region 24 in the charge generation region 29 in the Z-direction functions as a light-receiving region. Note that, the interposition region 25 is electrically connected to a ground electrode, and is grounded.

As illustrated in FIG. 3(a), charges moved to the charge accumulation region 24 are accumulated in the charge accumulation region 24. As described above, the gradient potential energy A that is gradient so that potential energy becomes lower as approaching the transfer region 35 is formed in the charge accumulation region 24. Accordingly, charges move in the charge accumulation region 24 toward the transfer region 35 side at a high speed.

During the charge accumulation process, electric potentials are applied to the first transfer gate electrode 43 and the second transfer gate electrode 44 so that the first potential energy ϕ43 of the region immediately below the first transfer gate electrode 43 and the second potential energy ϕ44 of the region immediately below the second transfer gate electrode 44 become higher than potential energy Pa of a lower end of the gradient potential energy A. The potential energy Pa of the lower end of the gradient potential energy A corresponds to potential energy of a boundary portion with the transfer region 35 in the charge accumulation region 24. Accordingly, charges do not move from the charge accumulation region 24 to the charge collection region 33 and are accumulated in the charge accumulation region 24.

In the example, the control unit 70 controls the voltages applied to the first transfer gate electrode 43 and the second transfer gate electrode 44 in two steps of ON and OFF. During the charge accumulation process, the voltages applied to the first transfer gate electrode 43 and the second transfer gate electrode 44 are set to OFF. The OFF-voltage applied to the first transfer gate electrode 43 is, for example, 0 V as in the OFF-voltage applied to the second transfer gate electrode 44. As illustrated in FIG. 3(a), in a state in which the voltages applied to the first transfer gate electrode 43 and the second transfer gate electrode 44 are OFF, the second potential energy ϕ44 is higher than the first potential energy ϕ43. Note that, as illustrated in FIG. 3(a), at the time of starting of the charge accumulation process, a constant amount of charges B remains in the charge collection region 33 and the channel region 34. Charges B are charges remaining in the charge collection region 33 and the channel region 34 at a reset process to be described later.

Next, a charge transfer process of transferring charges to the charge collection region 33 is executed. In the charge transfer process, electric potentials are applied to the first transfer gate electrode 43 and the second transfer gate electrode 44 so that after the first potential energy ϕ43 and the second potential energy ϕ44 become equal to or lower than the potential energy Pa of the lower end of the gradient potential energy A, the first potential energy ϕ43 and the second potential energy ϕ44 become higher than the potential energy Pa.

More specifically, first, as illustrated in FIG. 3(b), the voltages applied to the first transfer gate electrode 43 and the second transfer gate electrode 44 are set to ON, and the first potential energy ϕ43 and the second potential energy ϕ44 become equal to or lower than the potential energy Pa of the lower end of the gradient potential energy A. In this state, the second potential energy ϕ44 is equal to the potential energy Pa, and the first potential energy ϕ43 is lower than the potential energy Pa. Accordingly, charges accumulated in the charge accumulation region 24 move to a region immediately below the first transfer gate electrode 43 and the charge collection region 33. Charges are not accumulated in a region immediately below the second transfer gate electrode 44. In the state illustrated in FIG. 3(b), the first potential energy ϕ43 is equal to potential energy ϕ33 of the charge collection region 33. Note that, the potential energy ϕ33 of the charge collection region 33, and potential energy ϕ34 of the channel region 34 are lower than the potential energy Pa.

In this example, the ON-voltages of the first transfer gate electrode 43 and the second transfer gate electrode 44 are equal to each other. As illustrated in FIG. 3(b), in a state in which the voltages applied to the first transfer gate electrode 43 and the second transfer gate electrode 44 are set to ON, the second potential energy ϕ44 is higher than the first potential energy ϕ43.

Next, as illustrated in FIG. 4(a), while the voltage applied to the first transfer gate electrode 43 is set to ON, the voltage applied to the second transfer gate electrode 44 is set to OFF, and the second potential energy ϕ44 becomes higher than the potential energy Pa of the lower end of the gradient potential energy A. At this time, since charges are not accumulated in the region immediately below the second transfer gate electrode 44, moving of charges does not occur.

Next, as illustrated in FIG. 4(b), the voltage applied to the first transfer gate electrode 43 is set to OFF, and the first potential energy ϕ43 becomes higher than the potential energy Pa of the lower end of the gradient potential energy A. Accordingly, charges accumulated in the region immediately below the first transfer gate electrode 43 move to the charge collection region 33. In this manner, in the charge transfer process, after the second potential energy ϕ44 becomes higher than the potential energy Pa (FIG. 4(a)) from a state in which the first potential energy ϕ43 and the second potential energy ϕ44 are equal to or lower than the potential energy Pa (FIG. 3(b)), the first potential energy ϕ43 becomes higher than the potential energy Pa (FIG. 4(b)).

Even in any state of FIG. 3(b), FIG. 4(a), and FIG. 4(b), the second potential energy ϕ44 is higher than the first potential energy ϕ43. Accordingly, charges are suppressed from returning to the charge accumulation region 24 from the region immediately below the first transfer gate electrode 43.

Next, a read-out process of reading out charges accumulated in the charge collection region 33 is executed. Charges accumulated in the charge collection region 33 are read out by the above-described read-out circuit. Next, a reset process of resetting the charge collection region 33 is executed. In the reset process, an electric potential of the discharge gate electrode 42 is controlled so that the potential energy ϕ42 of a region immediately below the discharge gate electrode 42 is lowered. Accordingly, charges within the charge collection region 33 are discharged to the outside through the channel region 34, and the charge collection region 33 is reset. After completion of the reset process, the potential energy ϕ42 is returned to the original state.

### [Function and Effect]

In the optical sensor 1, the charge generation region 29 includes the avalanche multiplication region 23 that causes avalanche multiplication. Accordingly, the avalanche multiplication can be caused in the charge generation region 29, and high sensitivity can be realized. In addition, the charge generation region 29 includes the gradient potential energy formation region 59 that forms the gradient potential energy A that is gradient so that potential energy becomes lower as approaching the transfer region 35 in the charge generation region 29. Accordingly, the gradient potential energy A that is gradient so that potential energy becomes lower as approaching the transfer region 35 can be formed in the charge generation region 29, and a moving speed of charges in the charge generation region 29 can be increased. Hence, according to the optical sensor 1, charges can be transferred at a high speed even in a case where the area of the light-receiving region is large.

The optical sensor 1 includes the first transfer gate electrode 43, and the second transfer gate electrode 44 that is disposed on the side of charge generation region 29 with respect to the first transfer gate electrode 43. Accordingly, as described below, suppression of occurrence of a noise, or enlargement of a dynamic range is possible.

In the charge transfer process of transferring charges generated in the charge generation region 29 to the charge collection region 33, electric potentials are applied to the first transfer gate electrode 43 and the second transfer gate electrode 44 so that after the first potential energy ϕ43 that is potential energy of the region immediately below the first transfer gate electrode 43 and the second potential energy ϕ44 that is potential energy of the region immediately below the second transfer gate electrode 44 become equal to or lower than the potential energy Pa (potential energy of a boundary portion with the transfer region 35 in the charge generation region 29) of the lower end of the gradient potential energy A, the first potential energy ϕ43 and the second potential energy ϕ44 becomes higher than the potential energy Pa. Accordingly, charges can be transferred from the charge generation region 29 to the charge collection region 33 at a high speed by using the first transfer gate electrode 43 and the second transfer gate electrode 44, and charges can be suppressed from moving from the charge generation region 29 to the charge collection region 33 after charge transfer.

In the charge transfer process, electric potentials are applied to the first transfer gate electrode 43 and the second transfer gate electrode 44 so that the second potential energy ϕ44 becomes higher than the first potential energy ϕ43. Accordingly, charges can be suppressed from returning to the region immediately below the first transfer gate electrode 43 to the charge accumulation region 24 (charge generation region 29), and occurrence of a noise can be suppressed. In addition, it is possible to increase the read-out amount of charges by using capacity of the region immediately below the first transfer gate electrode 43, and a dynamic range can be broadened.

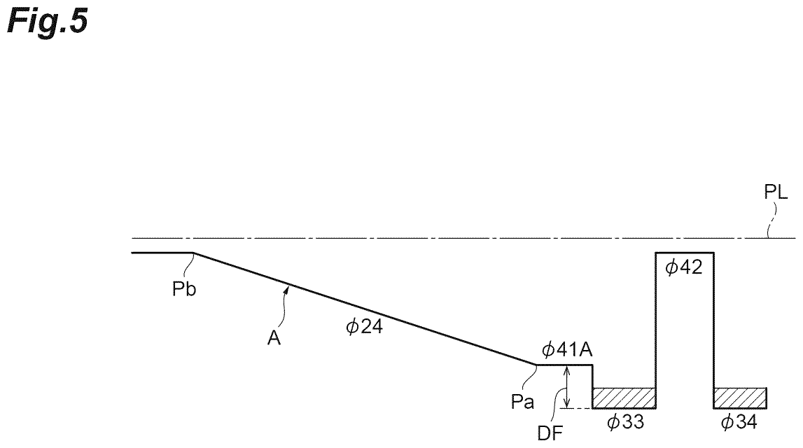

This point will be further described with reference to FIG. 5. FIG. 5 is a potential energy distribution diagram describing an operation example of an optical sensor according to a first modification example. A transfer gate electrode 41A of the first modification example is constituted by only a single electrode. Even in the first modification example, charge transfer can be performed by applying an electric potential to the transfer gate electrode 41A so that after potential energy ϕ41A that is potential energy of a region immediately below the transfer gate electrode 41A becomes equal to or lower than the potential energy Pa of the lower end of the gradient potential energy A, and the potential energy ϕ41A becomes higher than the potential energy Pa. Accordingly, as in the above-described embodiment, high sensitivity can be realized, and charges can be transferred at a high speed even in a case where the area of the light-receiving region is large.

However, in the first modification example, as illustrated in FIG. 5, the read-out amount of charges corresponds to a difference DF between the potential energy Pa of the lower end of the gradient potential energy A and the potential energy ϕ33 of the charge collection region 33. In contrast, in the above-described embodiment, since capacity of the region immediately below the first transfer gate electrode 43 can be used as the read-out amount of charges, as indicated by an arrow AR in FIG. 4(a) and FIG. 4(b), the read-out amount of charges increases in comparison to the case of the first modification example by the capacity of the region immediately below the first transfer gate electrode 43. In this manner, according to the above-described embodiment, the read-out amount of charges can be increased by using the capacity of the region immediately below the first transfer gate electrode 43, and a dynamic range can be broadened.

In a state in which the electric potential of the first transfer gate electrode 43 and the electric potential of the second transfer gate electrode 44 are equal to each other, the second potential energy ϕ44 is higher than the first potential energy ϕ43. Accordingly, the second potential energy ϕ44 can be made higher than the first potential energy ϕ43 by applying the same electric potential to the first transfer gate electrode 43 and the second transfer gate electrode 44. As a result, for example, it is possible to simplify a configuration for applying an electric potential in comparison to a case of making the second potential energy ϕ44 higher than the first potential energy ϕ43 by applying an electric potential different in a magnitude to the first transfer gate electrode 43 and the second transfer gate electrode 44.

The transfer region 35 includes the potential energy adjustment layer 36 for making the second potential energy ϕ44 higher than the first potential energy ϕ43. Accordingly, the second potential energy ϕ44 can be made higher than the first potential energy ϕ43 by the potential energy adjustment layer 36.

In a state in which the first potential energy ϕ43 and the second potential energy ϕ44 are equal to or lower than the potential energy Pa of the lower end of the gradient potential energy A in the charge transmission process, the second potential energy ϕ44 is equal to the potential energy Pa, and the first potential energy ϕ43 is lower than the potential energy Pa. Accordingly, charges can be suppressed from being accumulated in the region immediately below the second transfer gate electrode 44, and occurrence of a noise due to returning of charges to the charge accumulation region 24 (charge generation region 29) from the region immediately below the second transfer gate electrode 44 can be suppressed.

In the charge transfer process, after the second potential energy ϕ44 becomes higher than the potential energy Pa from a state in which the first potential energy ϕ43 and the second potential energy ϕ44 are equal to or lower than the potential energy Pa of the lower end of the gradient potential energy A, the first potential energy ϕ43 becomes higher than the potential energy Pa. Accordingly, it is possible to reliably suppress charges from returning to the charge accumulation region 24 (charge generation region 29) from the region immediately below the first transfer gate electrode 43, and it is possible to reliably suppress occurrence of a noise. The reason for this is because it is possible to make an electric potential barrier between the region immediately below the first transfer gate electrode 43 and the charge accumulation region 24 higher in comparison to a case of simultaneously raising the first potential energy ϕ43 and the second potential energy ϕ44.

In a case of forming the gradient potential energy A in the charge generation region 29 in a configuration in which the charge generation region 29 includes the avalanche multiplication region 23, it is difficult to secure a gradient height of the gradient potential energy A due to the following reason. First, it is considered that potential energy Pb of an upper end of the gradient potential energy A is raised so as to raise the gradient height. However, it is necessary to make the potential energy Pb lower than a punch-through line PL illustrated in FIG. 5 in order for short-circuiting not to occur between the interposition region 25 and the semiconductor region 21. In addition, it is necessary to lower an electric potential of the upper end of the gradient potential energy A so as to raise the potential energy Pb. However, in this case, there is a concern that a leak current may occur between the interposition region 25 and the semiconductor region 21 at the upper end of the gradient potential energy A. Therefore, there is a limit in raising of the potential energy Pb. In addition, since a reverse bias voltage is lowered at the upper end of the gradient potential energy A in which the electric potential is low, there is a concern that a multiplication rate in a portion corresponding to the upper end of the gradient potential energy A in the avalanche multiplication region 23 may decrease.

Second, it is considered that the potential energy Pa (depletion electric potential) of the lower end of the gradient potential energy A is made low so as to raise the gradient height. However, when the potential energy Pa is lowered, the difference DF (FIG. 5) between the potential energy Pa and the potential energy ϕ33 of the charge collection region 33 also decreases, and thus the read-out amount of charges decreases. Therefore, there is also a limit in lowering of the potential energy Pb.

In contrast, in the optical sensor 1 of the above-described embodiment, as described above, since charges are transferred to the charge collection region 33 by using the first transfer gate electrode 43 and the second transfer gate electrode 44, occurrence of a noise can be suppressed, the read-out amount of charges can be increased by using the capacity of the region immediately below the first transfer gate electrode 43, and a dynamic range can be broadened. As a result, a large gradient height of the gradient potential energy A can be secured while securing a large dynamic range.

The gradient potential energy formation region 59 is located on the first side with respect to the avalanche multiplication region 23. Accordingly, a ratio of charges existing in a region close to the transfer gate electrode 41 increases, and charges can be transferred at a higher speed. In addition, since the gradient potential energy A is formed near the transfer gate electrode 41, charges can be transferred at a higher speed.

As the gradient potential energy formation region 59 includes the second region 52, the third region 53, and the fourth region 54 which are arranged so that an impurity concentration increases as approaching the transfer region 35. Accordingly, the gradient potential energy A can be preferably formed in the charge generation region 29.

The charge generation region 29 has the embedded photodiode structure. Accordingly, occurrence of a dark current in the charge generation region 29 can be suppressed.

### Modification Example

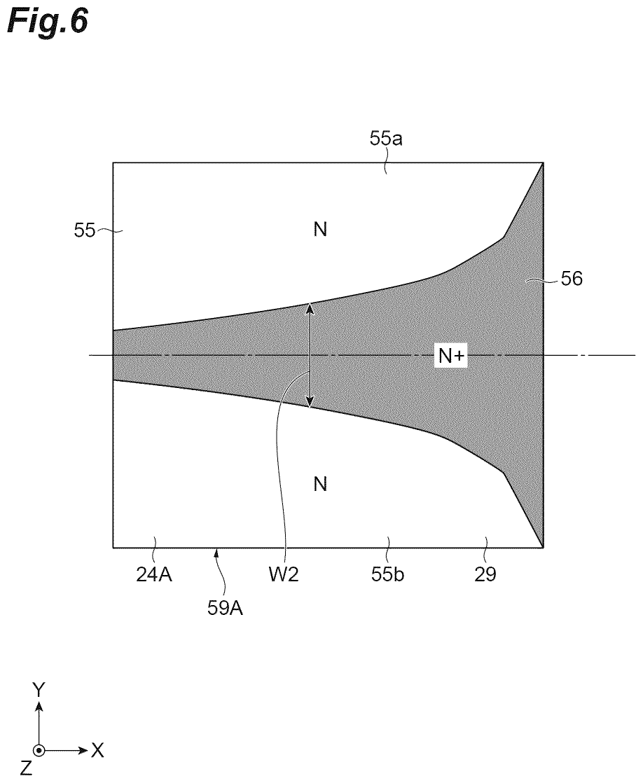

A charge accumulation region 24A of a second modification example illustrated in FIG. 6 includes a first region (first semiconductor region) 55 and a second region (second semiconductor region) 56. The first region 55 includes a first portion 55a and a second portion 55b. The second region 56 is disposed between the first portion 55a and the second portion 55b in the Y-direction. The first region 55 and the second region 56 are n-type regions. The second region 56 has an impurity concentration higher than that of the first region 55. The impurity concentration of the first region 55 is approximately 1×10¹³ to 1×10¹⁶ cm⁻³, and the impurity concentration of the second region 56 is approximately 1×10¹⁶ to 1×10¹⁹ cm⁻³. The first region 55 may be a p-type region.

The second region 56 is adjacent to the transfer region 35 in the X-direction. A width (length along the Y-direction) W2 of the second region 56 increases as approaching the transfer region 35. The charge accumulation region 24A including the first region 55 and the second region 56 function as a gradient potential energy formation region 59A that forms the gradient potential energy A that is gradient so that the potential energy is lower as approaching the transfer region 35. The gradient potential energy formation region 59A is located on the first side with respect to the avalanche multiplication region 23 in the Z-direction. According to the second modification example, high sensitivity can be realized and charges can be transferred at a high speed even in a case where the area of the light-receiving region is large as in the above-described embodiment.

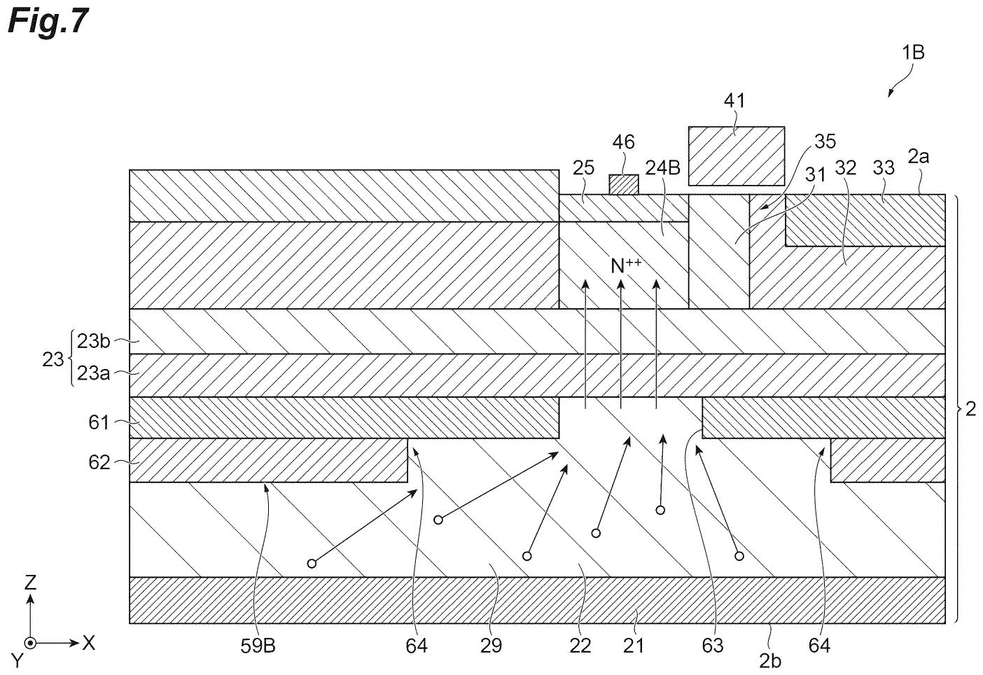

In an optical sensor 1B of a third modification example illustrated in FIG. 7, a gradient potential energy formation region 59B is located on the second side with respect to the avalanche multiplication region 23. The gradient potential energy formation region 59B includes a first semiconductor layer 61, and a second semiconductor layer 62 located on the second side with respect to the first semiconductor layer 61. A through-hole 63 that passes through the first semiconductor layer 61 along the Z-direction is formed in the first semiconductor layer 61.

The first semiconductor layer 61 and the second semiconductor layer 62 are p-type regions. An impurity concentration of the first semiconductor layer 61 and the second semiconductor layer 62 is approximately 1×10¹⁴ to 1×10¹⁶ cm⁻³. The first semiconductor layer 61 and the second semiconductor layer 62 may be regarded to constitute a first multiplication region 23a of the avalanche multiplication region 23. In other words, the avalanche multiplication region 23 may also be regarded to include the first semiconductor layer 61 and the second semiconductor layer 62.

In the third modification example, a stepped portion 64 is formed between the first semiconductor layer 61 and the second semiconductor layer 62, and thus the gradient potential energy A is formed. A part of a surface of the first semiconductor layer 61 is not covered with the second semiconductor layer 62, and thus the stepped portion 64 is formed between the part and the second semiconductor layer 62. In this example, a pair of the stepped portions 64 are provided, and respectively extend along the Y-direction. The through-hole 63 is disposed between the pair of stepped portions 64 in the X-direction.

The charge generation region 29 further includes a charge accumulation region 24B provided on the first side with respect to the avalanche multiplication region 23 in addition to the gradient potential energy formation region 59B. The charge accumulation region 24B is an n-type region. An impurity concentration of the charge accumulation region 24B is approximately 1×10¹⁶ to 1×10¹⁹ cm⁻³.

The through-hole 63 overlaps a boundary portion with the transfer region 35 in the charge generation region 29 in the Z-direction. In this example, the through-hole 63 overlaps the charge accumulation region 24B in the Z-direction. In the third modification example, charges collected by the gradient potential energy A reach the avalanche multiplication region 23 through the through-hole 63. Charges multiplied by the avalanche multiplication region 23 are accumulated in the charge accumulation region 24B. The charges accumulated in the charge accumulation region 24B are transferred to the charge collection region 33 by using the transfer gate electrode 41. Note that, in FIG. 7, the transfer gate electrode 41 is drawn to be constituted by a single electrode, but the transfer gate electrode 41 may include the first transfer gate electrode 43 and the second transfer gate electrode 44 as in the above-described embodiment. In FIG. 7, a part of the electrode layer 4, the protective layer 6, and the like are not illustrated. The ground electrode 46 disposed on the interposition region 25 is illustrated in the drawing.

According to the third modification example, high sensitivity can be realized and charges can be transferred at a high speed even in a case where the area of the light-receiving region is large as in the above-described embodiment. In addition, the gradient potential energy formation region 59B is located on the second side with respect to the avalanche multiplication region 23. In this structure, the above-described limit relating to the gradient height of the gradient potential energy A is less likely to occur. Accordingly, the gradient of the gradient potential energy A can be enlarged, and charges can be transferred at a higher speed. In addition, since charges collected by the gradient potential energy A are multiplied in the avalanche multiplication region 23, a multiplication occurrence site can be limited, and uniformity of multiplication can be raised.

In the gradient potential energy formation region 59B, since the stepped portion 64 is formed between the first semiconductor layer 61 and the second semiconductor layer 62, the gradient potential energy A is formed. Accordingly, the gradient potential energy A can be preferably formed in the charge generation region 29.

The through-hole 63 formed in the first semiconductor layer 61 overlaps a boundary portion with the transfer region 35 in the charge generation region 29 in the Z-direction. Accordingly, charges guided by the gradient potential energy A can be collected in the boundary portion with the transfer region 35 in the charge generation region 29.

The present disclosure is not limited to the above-described embodiment and modification examples. For example, in a material and a shape of each configuration, various materials and shapes can be employed without limitation to the above-described material and shape.

In the above-described embodiment, the second potential energy ϕ44 is made higher than the first potential energy ϕ43 by applying the same electric potential to the first transfer gate electrode 43 and the second transfer gate electrode 44. However, an additional bias circuit may be provided, and the second potential energy ϕ44 may be made higher than the first potential energy ϕ43 by applying electric potentials different in a magnitude to the first transfer gate electrode 43 and the second transfer gate electrode 44, respectively. In this case, at the start and at the end of the charge transfer process, the first potential energy ϕ43 and the second potential energy ϕ44 may be equal to each other.

The transfer gate electrode 41 may be constituted by a single electrode. Even in this case, the second potential energy ϕ44 can be made higher than the first potential energy ϕ43 by forming the potential energy adjustment layer 36 as in the above-described embodiment. For example, the potential energy adjustment layer 36 can be formed on a lower side of a portion corresponding to the second transfer gate electrode 44 in the transfer gate electrode 41 constituted by a single electrode.

The first potential energy ϕ43 and the second potential energy ϕ44 may simultaneously become higher than the potential energy Pa from a state in which the first potential energy ϕ43 and the second potential energy ϕ44 are equal to or lower than the potential energy Pa of the lower end of the gradient potential energy A. The respective conductivity types such as the p-type and the n-type may be reversed from the above-described types. The plurality of pixels 10 may be one-dimensionally arranged along the first surface 2a of the semiconductor layer 2. The optical sensor 1 may include a single pixel 10. The optical sensor 1 may be a distance measurement sensor that acquires a distance image of an object (image including information relating to a distance d up to an object) by using an indirect TOF method. The optical sensor 1 may include two or more charge collection regions 33 in each pixel 10. The optical sensor 1 may include two or more transfer gate electrodes 41 in each pixel 10.

In the above-described embodiment and modification examples, the avalanche multiplication region 23 may not be formed. That is, the charge generation region 29 may not include the avalanche multiplication region 23. According to this configuration, charges can also be transferred at a high speed even in a case where the area of the light-receiving region is large as in the above-described embodiment.

### REFERENCE SIGNS LIST

1, 1B: optical sensor, 23: avalanche multiplication region, 29: charge generation region, 33: charge collection region, 35: transfer region, 36: potential energy adjustment layer, 41, 41A: transfer gate electrode, 43: first transfer gate electrode, 44: second transfer gate electrode, 52: second region (semiconductor region), 53: third region (semiconductor region), 54: fourth region (semiconductor region), 55: first region (first semiconductor region), 55a: first portion, 55b: second portion, 56: second region (second semiconductor region), 59, 59A, 59B: gradient potential energy formation region, 61: first semiconductor layer, 62: second semiconductor layer, 63: through-hole, 64: stepped portion, A: gradient potential energy, Pa: potential energy at lower end of gradient potential energy (potential energy at boundary portion with transfer region in charge generation region), W2: width, ϕ43: first potential energy, ϕ44: second potential energy.

1: An optical sensor comprising:
a charge generation region that generates charges in response to incident light;
a charge collection region to which charges generated in the charge generation region are transferred; and
at least one transfer gate electrode disposed on a transfer region between the charge generation region and the charge collection region,
wherein the charge generation region includes,
an avalanche multiplication region that causes avalanche multiplication, and
a gradient potential energy formation region that forms gradient potential energy in the charge generation region, the gradient potential energy being gradient so that potential energy becomes lower as approaching the transfer region.

2: The optical sensor according to claim 1,
wherein the at least one transfer gate electrode includes a first transfer gate electrode and a second transfer gate electrode disposed on a side of the charge generation region with respect to the first transfer gate electrode.

3: The optical sensor according to claim 2,
wherein in a charge transfer process of transferring the charges generated in the charge generation region to the charge collection region, electric potentials are applied to the first transfer gate electrode and the second transfer gate electrode so that after first potential energy that is potential energy of a region immediately below the first transfer gate electrode, and second potential energy that is potential energy of a region immediately below the second transfer gate electrode become equal to or lower than potential energy of a boundary portion with the transfer region in the charge generation region, the first potential energy and the second potential energy become higher than the potential energy of the boundary portion.

4: The optical sensor according to claim 3,
wherein in the charge transfer process, electric potentials are applied to the first transfer gate electrode and the second transfer gate electrode so that the second potential energy becomes higher than the first potential energy.

5: The optical sensor according to claim 4,
wherein in a state in which an electric potential of the first transfer gate electrode and an electric potential of the second transfer gate electrode are equal to each other, the second potential energy is higher than the first potential energy.

6: The optical sensor according to claim 5,
wherein the transfer region includes a potential energy adjustment layer for making the second potential energy higher than the first potential energy.

7: The optical sensor according to claim 3,
wherein in a state in which the first potential energy and the second potential energy in the charge transfer process are equal to or lower than the potential energy of the boundary portion, the second potential energy is equal to the potential energy of the boundary portion and the first potential energy is lower than the potential energy of the boundary portion.

8: The optical sensor according to claim 3,
wherein in the charge transfer process, after the second potential energy becomes higher than the potential energy of the boundary portion from a state in which the first potential energy and the second potential energy are equal to or lower than the potential energy of the boundary portion, the first potential energy becomes higher than the potential energy of the boundary portion.

9: The optical sensor according to claim 1,
wherein the avalanche multiplication region is formed in a layer shape along a predetermined plane, and
when a side where the transfer gate electrode is located with respect to the avalanche multiplication region in a direction orthogonal to the plane is set as a first side, and a side opposite to the first side is set as a second side, the gradient potential energy formation region is located on the first side with respect to the avalanche multiplication region.

10: The optical sensor according to claim 9,
wherein the gradient potential energy formation region includes a plurality of semiconductor regions arranged so that an impurity concentration becomes higher as approaching the transfer region.

11: The optical sensor according to claim 9,
wherein the gradient potential energy formation region includes a first semiconductor region including a first portion and a second portion, and a second semiconductor region which has an impurity concentration higher than an impurity concentration of the first semiconductor region and is disposed between the first portion and the second portion, and of which a width increases as approaching the transfer region.

12: The optical sensor according to claim 1,
wherein the avalanche multiplication region is formed in a layer shape along a predetermined plane, and
when a side where the transfer gate electrode is located with respect to the avalanche multiplication region in a direction orthogonal to the plane is set as a first side, and a side opposite to the first side is set as a second side, the gradient potential energy formation region is located on the second side with respect to the avalanche multiplication region.

13: The optical sensor according to claim 12,
wherein the gradient potential energy formation region includes a first semiconductor layer, and a second semiconductor layer located on the second side with respect to the first semiconductor layer, and
the gradient potential energy is formed due to formation of a stepped portion between the first semiconductor layer and the second semiconductor layer.

14: The optical sensor according to claim 13,
wherein a through-hole is formed in the first semiconductor layer, and
the through-hole overlaps a boundary portion with the transfer region in the charge generation region in a direction orthogonal to the plane.

15: The optical sensor according to claim 1,
wherein the charge generation region has an embedded photodiode structure.
